(19) United States
(12) Patent Application Publication
(10) Pub. No.: US 2019/0157574 A1
(43) Pub. Date: May 23, 2019

(54) Phosphorescence Device Containing Heterocyclic Phosphate Metal Complexes

(71) Applicant: AAC Technologies Pte. Ltd., Singapore city (SG)

(72) Inventors: Youxuan Zheng, Shenzhen (CN); Yi Pan, Shenzhen (CN); Yi Wang, Shenzhen (CN); Zhengguang Wu, Shenzhen (CN); Jinglin Zuo, Shenzhen (CN); Jie Zhou, Shenzhen (CN); Da Huang, Shenzhen (CN)

(21) Appl. No.: 15/964,241

(22) Filed: Apr. 27, 2018

(30) Foreign Application Priority Data
Nov. 17, 2017 (CN) 201711144368.5

(51) Int. Cl. H01L 51/00; C07F 15/00; C09K 11/06

(52) U.S. Cl. CPC H01L 51/0085; C07F 15/0033; C09K 11/06; H01L 51/5016; H01L 51/006; H01L 51/0094; H01L 51/0059

(57) ABSTRACT

The invention relates to organic electroluminescent devices, and discloses a phosphorescence device containing heterocyclic phosphoric acid metal complexes. The phosphorescence device provided by the invention contains metal complexes of heterocyclic phosphoric acid auxiliary ligands, and the glass transition temperature of the hole transport material of phosphorescence device is not lower than 85° C. Because a hole transport material with high vitrification temperature is used, the device provided by the invention can overcome the instability of the device and the adverse effect on the service life of the device when the glass transition temperature of the working device when the ambient temperature is above 30-40° C. and the working device temperature is close to that of the hole transport material. Compared with the devices based on FIrpic and TAPC, the phosphorescence device provided by the invention not only has higher device efficiency, but also has better high temperature stability.

### FIELD OF THE PRESENT DISCLOSURE

The invention relates to the technical field of an organic electroluminescent device, in particular to a luminescent device using a metal complex containing heterocyclic phosphoric acid.

### DESCRIPTION OF RELATED ART

In the field of display or lighting, in order to obtain white light or full color, blue luminescent materials must be used. In the prior art, the blue luminescent material, especially the blue phosphorescence material, is usually doped with FIrpic. Because the color of FIrpic is sky blue, practical application is limited.

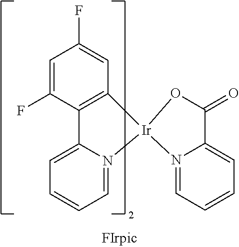

The inventor of the present invention has developed a metal complex material similar to FIrpic, the representative structure of which is shown in the following figure, except that FIrpic is a pyridinic acid. (dfppy)2Ir(ppp) and (dfppy)2Ir(dpp) are pyridine phosphoric acid.

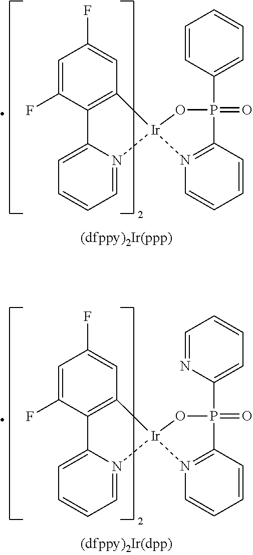

The data on the physical properties of (dfppy)2Ir(ppp) and (dfppy)2Ir(dpp) are as follows:

| Compound | T_{d}^{a}[° C.] | λ_{abs}[nm] | λₑₘ[nm] | Φ^{b}[%] | T^{c}[μs] | Band gap[eV] | HOMO/LUMO^{d}[eV] |
|---|---|---|---|---|---|---|---|
| (dfppy)₂Ir(ppp) | 389 | 256/379 | 471/497 | 35 | 1.44 | 2.95 | −5.95/−3.00 |
| (dfppy)₂Ir(dpp) | 396 | 256/377 | 470/496 | 25 | 1.34 | 3.01 | −5.96/−2.95 |

Compared with FIrpic, the blue shift of (dfppy)2Ir(ppp) and (dfppy)2Ir(dpp) the emission spectra is 5-6 nm, and the blue shift is very obvious. The simple device results show that the device efficiency is also superior to that of FIrpic.

The inventor of the invention has applied for the relevant patents on the basis of (dfppy)2Ir(ppp) and (dfppy)2Ir(dpp), followed by the results of document disclosure.

The related patents are:

The patent CN105837638A discloses a series of metal iridium complexes with 2,3,4-trifluorophenyl pyridine derivativeare as the host ligands with heterocyclic phosphoric acid as the auxiliary coligand.

The patent CN105837629A discloses a series of heterocyclic phosphoric acids and their preparation methods.

The patent CN105646595A discloses a series of metal iridium complexes with 2,4-difluoro-3-trifluoromethylphenyl pyridine derivatives as the host ligands and heterocyclic phosphoric acid as the auxiliary coligand.

The patent CN105646596A discloses a series of metal iridium complexes with aromatic ring heterocyclic nitrogen as the host coligand and heterocyclic phosphoric acid as the auxiliary coligand.

The patent CN105601677A discloses a series of metal iridium complexes with 2,4-difluorophenyl pyridine derivatives as the host ligands and heterocyclic phosphoric acid as the auxiliary coligand.

The patented CN105566399A discloses a series of metal iridium complexes with 2,4-difluoro-3-cyanophenyl pyridine derivatives as the host ligands and heterocyclic phosphoric acid as the auxiliary coligand.

Patent CN105669767A discloses a series of metal iridium complexes with 2,4-difluoropyridyl pyridine derivatives as the host ligands and heterocyclic phosphoric acid as the auxiliary coligand.

The patent CN105669768A discloses a series of metal iridium complexes with 2,4-bis (trifluoromethyl) phenyl pyridine derivatives as the host ligands and heterocyclic phosphoric acid as the auxiliary coligand.

Relevant documents include: Science Report DOI: 10.1038/srep38478; Organic Electronics 42 (2017) 141-145, DOI: 10.1016/j.orge1.2016.12.032.

However, the inventor of the invention further analyzes the existing phosphorescence device and finds that there is is still a serious problem, that is, the thermal stability of the device is poor. The thermal stability of the device is directly related to the glass transition temperature of the material used (but there is no quantitative relationship). Among the existing devices, TAPC (a typical hole transport material), which uses the new blue light material mentioned above, is used as the glass transition material. The glass transition temperature of the material is only 78° C. When the device temperature reaches 78° C., the performance of TAPC will inevitably change, which will lead to the device cannot be used. Therefore, the use temperature of TAPC devices must be lower than 78 degrees.

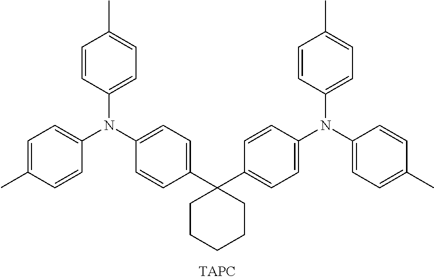

Because the OLED device is a current-driven luminescent device, when the current passes, it will produce corresponding Joule heat. There are some related papers in the industry which point out that when the OLED device with various structures and substrates is in operation, the actual device temperature will be 10-30 degrees higher than the ambient temperature. Therefore, when the ambient temperature of the device is 30-40 degrees, the actual temperature of the device is close to the glass transition temperature of TAPC compounds. Such devices obviously have poor thermal stability and have a very short life span that cannot be adapted to industrial needs.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

In order to make the purpose, technical scheme and advantages of the invention more clear, the embodiments of the invention will be described in detail in combination with the attached Chemical Structure. However ordinary technicians in the art can understand that in various embodiments of the present invention many technical details are presented in order to enable the reader to better understand the invention. However, even without these technical details and various changes and modifications based on the following embodiments, the technical schemes claimed for protection by the claims of the present invention can be achieved.

The first embodiment of the invention relates to the composition of a phosphorescence device containing a metal complex of heterocyclic phosphoric acid.

The device of the embodiment of the invention contains a metal complex with heterocyclic phosphoric acid as the auxiliary ligands, while the glass transition temperature of the hole transport material of the device is not less than 85° C.

The auxiliary ligands of the metal complexes, as shown in the general formula (I):

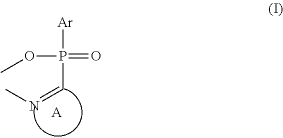

Among them, the ring A is an aromatic group with at least a nitrogen atom, Ar is an aromatic group.

In some specific embodiments of the invention, the ring A may be a single ring or a parallel ring, and a single ring is preferred. When the ring A is a single ring, a quaternion ring or a six-member ring is preferred, and a six-element ring is more preferred. When A is a six-member ring, the pyridine ring, pyrimidine ring, pyrazine ring and triazine ring are preferred, and the pyridine ring is more preferred. When ring A is a six-member ring, it is preferably substituted by hydrogen atom, deuterium atom, fluorine atom, alkyl, alkoxy, aryl and hetero-aryl group, and more preferably substituted by hydrogen atom and alkyl.

In some specific embodiments of the present invention, an Ar may be a single ring or a parallel ring, and the single ring is preferred. When Ar is a single ring, a quaternion ring or a six-element ring is preferred, and a six-element ring is more preferred. When Ar is a six-member ring, phenyl, pyridine, pyrimidine and pyrazine rings are preferred, and the phenyl and pyridine groups are more preferred. When Ar is a six-member ring, it is preferably substituted by hydrogen atom, deuterium atom, fluorine atom, alkyl, alkoxy, aryl, hetero-aryl group, and more preferably substituted by hydrogen atom and alkyl.

In some specific embodiments of the invention, the metal of the metal complex is preferred from Ir, Pt, Os, Ru, and Ir is more preferred.

In some specific embodiments of the present invention, the metal complex also includes a principal ligand having a structure as shown in the generic (II):

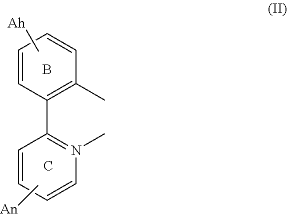

Among them, the ring B is a six-member ring, the ring C is a nitrogen-containing heterocyclic, and Ah and An are substituent groups.

The ring B is preferred as phenyl, pyridine ring, pyrimidine ring, pyrazine ring, and the phenyl, pyridine group are preferred.

The ring C is preferred as the pyridine ring, pyrimidine ring, pyrazine ring, and pyridine group is more preferred.

Ah is preferred as hydrogen, deuterium, halogen, alkyl, halogen substituted alkyl, aryl, hetero-aryl, cyanide, and the hydrogen, fluorine, trifluoromethyl and cyanide are more preferred.

An is preferred as hydrogen, deuterium, halogen, alkyl, alkoxy, aryl, hetero-aryl, aramido, hetero-arylamine.

There may be more than one Ah, An groups, when more than one, the substitution group can be different.

In some specific embodiments of the invention, the hole transport material with high glass transition temperature has the following structure:

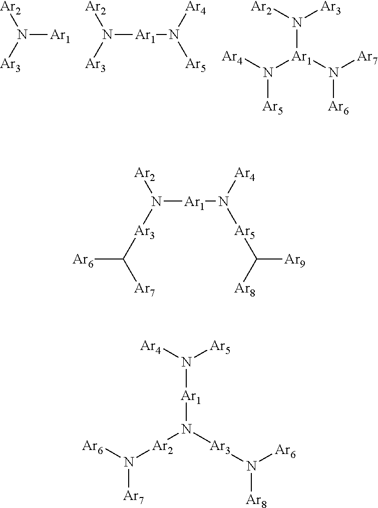

Among them, Ar₁, Ar₂, Ar₃, Ar₄, Ar₅, Ar₆, Ar₇, Ar₈, Ar₉ denote the aromatic groups, nitrogen-containing aromatic groups, oxygen-containing aromatic groups, sulfur-containing aromatic groups, Aromatic groups containing boron and aromatic groups containing silicon. Aromatic groups containing phosphorus independently, respectively; the aromatic groups may be substituted by substituents. The substituents are hydrogen, halogen, alkyl, naphthyl, hetero-alkyl, aromatic alkyl, alkoxy, aromatic alkyl, silyl, alkyne, alkenyl, aryl, heteraryl, acyl, carbonyl, ester, cyanide and their combinations.

In some specific embodiments of the present invention, Ar₁, Ar₂, Ar₃, Ar₄, Ar₅, Ar₆, Ar₇, Ar₈, Ar₉ are selected from phenyl, biphenyl, triphenyl, tetraphenyl, toluene, tert-Butylbenzene phenyl, methoxy, Naphthyl, anthracene, phenanthroline, pyrene, benzophenyl, carbazole, thiophene, fluorene.

In some specific embodiments of the invention, the glass transition temperature of the hole transport material is greater than 90° C. More preferably, the vitrification temperature of the hole-transport material is higher than 100° C. More preferably, the glass transition temperature of the hole-transport material is higher than 110° C.

In some specific embodiments of the invention, the hole transport material has both a hole injection function and an electronic blocking function.

In some specific embodiments of the present invention, the specific configuration of the hole transmission material is unrestricted. In particular, the hole transmission material in the embodiment of the present invention is provided for example but is not limited. The hole transport material reported in the following documents may be used (or the method provided in the following literature report is used for the preparation of the hole transport material), such as the hole transport materials disclosed in Chemical Review (Chem. Rev. 2007). Journal of the Society for Documentation and Information Display, (JSID, 2015,23,182.DOI:10.1002/jsid.320), Chemical Progress (Chemical Progress: 2003, 15, 495), Organic Letters (Org. Lett. 2010, 12, 404-407), provided that the glass transition temperature is over 85 degrees; the hole-transfer materials that are disclosed prior to patent application may also be used (or the preparation of hole-transfer materials may be carried out by a method of prior patent disclosure), such as the hole transport material disclosed in CN100521846C, US20170018721, EP2860171, provided that the glass transition temperature is over 85 degrees.

As mentioned above, the source of the hole-transport materials is extensive, but generally their synthesis methods are not substantially different, mainly by coupling methods, such as Grinard reaction, Wurtz reaction, suzuki reaction, Heck reaction, Stille reaction, Negishi reaction and Sonogashira reaction, these are well known in the field of organic synthesis.

In some specific embodiments of the invention, the hole transmission material used has one of the following structures:

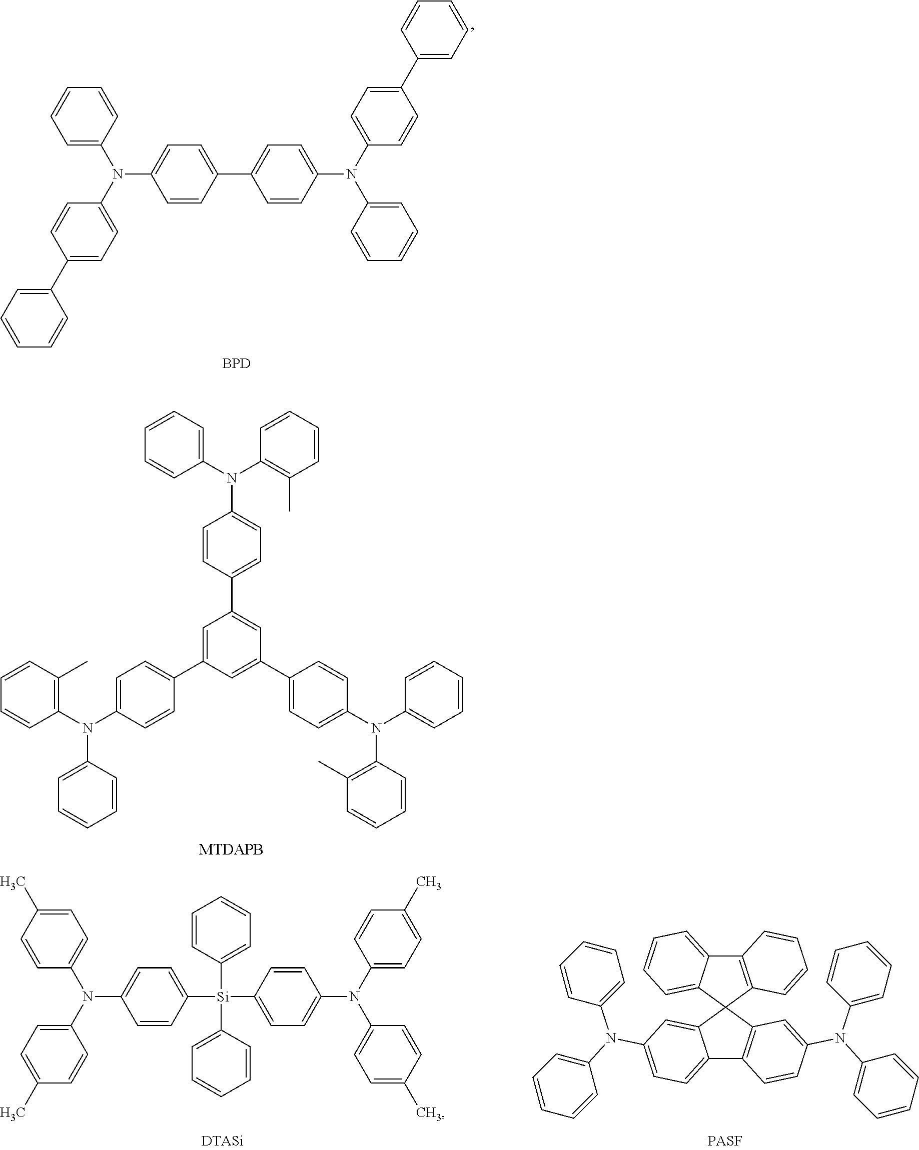 [SMILES: c1ccc(-c2ccc(N(c3ccccc3)c3ccc(-c4ccc(N(c5ccccc5)c5ccc(-c6ccccc6)cc5)cc4)cc3)cc2)cc1 ; "BPD" ; Cc1ccccc1N(c1ccccc1)c1ccc(-c2cc(-c3ccc(N(c4ccccc4)c4ccccc4C)cc3)cc(-c3ccc(N(c4ccccc4)c4ccccc4C)cc3)c2)cc1 ; Cc1ccc(N(c2ccc(C)cc2)c2ccc([Si](c3ccccc3)(c3ccccc3)c3ccc(N(c4ccc(C)cc4)c4ccc(C)cc4)cc3)cc2)cc1 ; c1ccc(N(c2ccccc2)c2ccc3c(c2)C2(c4ccccc4-c4ccccc42)c2cc(N(c4ccccc4)c4ccccc4)ccc2-3)cc1]

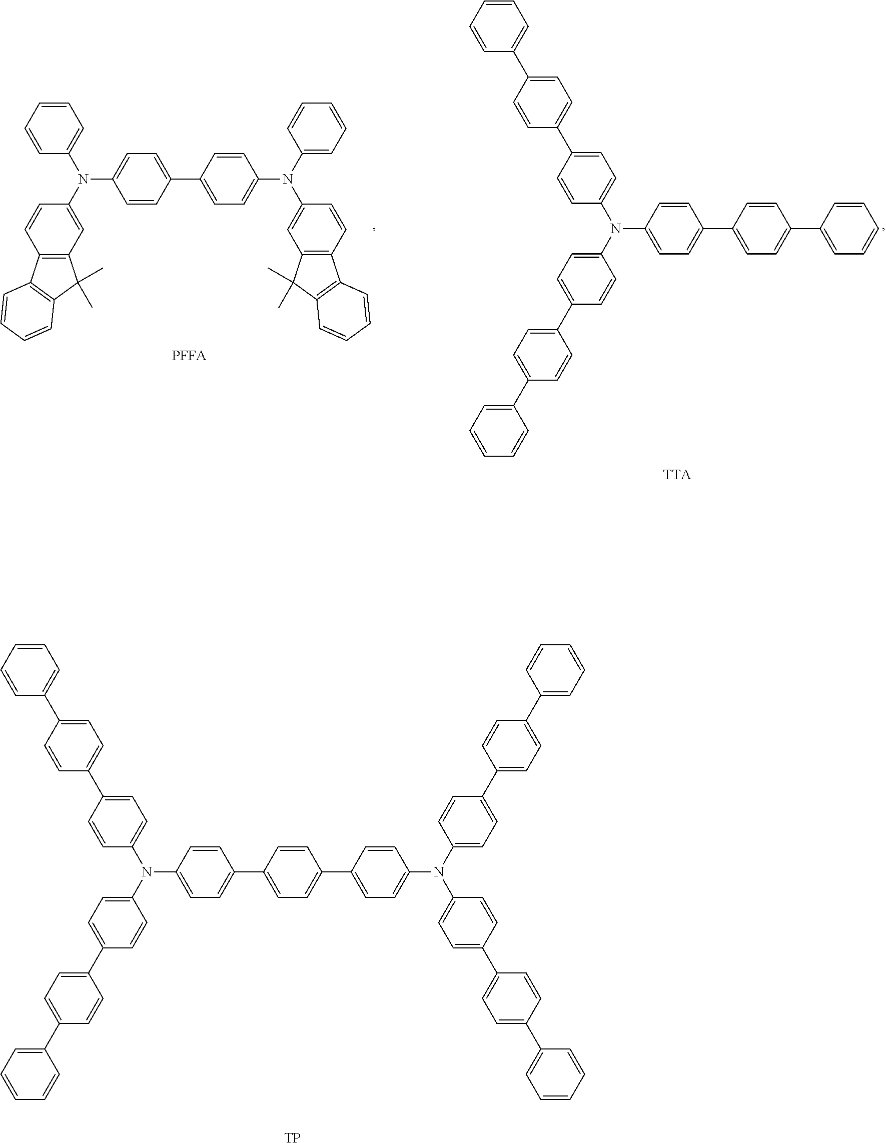 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; "PFFA" ; c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; "TTA" ; c1ccc(-c2ccc(-c3ccc(N(c4ccc(-c5ccc(-c6ccccc6)cc5)cc4)c4ccc(-c5ccc(-c6ccc(N(c7ccc(-c8ccc(-c9ccccc9)cc8)cc7)c7ccc(-c8ccc(-c9ccccc9)cc8)cc7)cc6)cc5)cc4)cc3)cc2)cc1 ; "TP"]

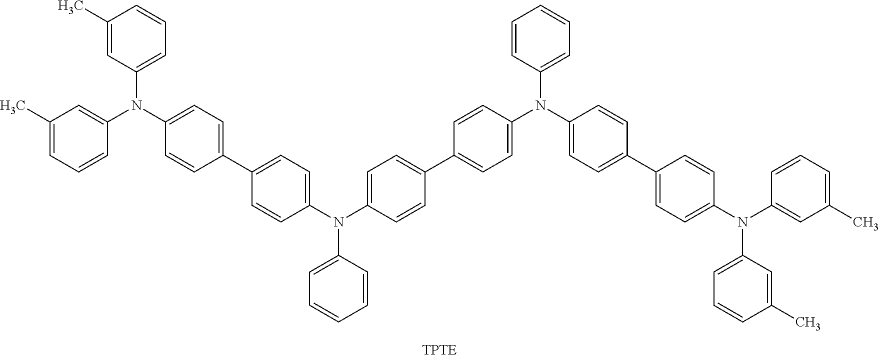

It is worth noting that, the metal complexes containing heterocyclic phosphoric acid auxiliary ligands and hole-transport materials used in the above embodiments can be prepared by a method disclosed prior to the application date of the invention or may be purchased through commercial channels.

The metal complexes containing heterocyclic phosphoric acid auxiliary ligands may be prepared using the method disclosed in the prior patent application described in the background technology. Specifically, BPD can be prepared by using the prior patent application US2011257404 method, MTDAPB can be prepared by the method provided by J. Chem. Soc., Perkin Trans 1, 2000, 16, 2695, DTASi can be prepared with reference to method published in the literature Chem A European Journal 2007 13 5713, and PASF can be prepared by the method disclosed by prior patent application US201315403, and PFFA can be prepared with reference to the method disclosed in the prior patent application US2007287029, and TTA may be prepared with reference to the method disclosed by the prior patent application US20040062951, and TP can be prepared by using the method provided by the prior patent application WO2016058504, and TPTE can be prepared with reference to the method provided by the published literature (Chem. Comm., 1996, 18, 2175).

The second embodiment of the invention relates to a fabricating process of the device.

The fabrication of the device can be carried out in the following ways: firstly, the appropriate anode is selected for introducing holes, the anode surface can be evaporated by other materials to change the work function of the anode, and then the organic luminescent layer can be evaporated. While performing both hole transmission and luminescence function, and then the electron transport layer continues to vaporize, in order to transport electrons, and then continue to evaporate the cathodes to introduce electrons.

It can also be carried out in the following ways: firstly, the appropriate anode is selected for the introduction of holes, the anode surface can be evaporated other materials to change the work function of the anode, and then the hole transport layer continues to evaporate on top, which is used to transfer holes, then the organic luminescent layer continues to vaporize for luminescence, and then the electron transport layer to continue to vaporize for transferring electrons, and then the cathode continues to evaporate.

It can also be carried out in the following ways: firstly, the appropriate anode is selected for the introduction of holes, the anode surface can be evaporated to other materials to change the work function of the anode, and then the hole transport layer continues to vaporize. Then, the organic luminescent layer is evaporated and the luminescence function and electron transport function are taken into account, and then the cathode is continued to be evaporated.

It can also be chosen as follows: firstly, the appropriate anode is selected for the introduction of holes. Other materials can be evaporated on the anode surface to change the work function of the anode, and then the hole implantation layer can be continued to be evaporated. The utility model is used to improve the injection efficiency of the hole and then continue to vaporize the hole transport layer to transfer the hole, then continue to vaporize the organic luminescent layer, then continue to vaporize the electron transport layer, and then continue the evaporation of the electron injection layer. Improve the efficiency of electron injection, and then continue to evaporate a layer of cathode.

The hole injection layer, hole transport layer, luminescent layer, electron transport layer and electron injection layer can be one layer or multi-layer. The thickness of monolayer organic layer is 10-100 nm. The luminescent layer is a mixed layer, comprising a main material and a phosphorescent material. The doping ratio of the mixed layer is 1-20%.

A third embodiment of the invention relates to a comparative test example.

In order to compare and explain the excellent characteristics of the device, the fabrication method of the following device structure is adopted: the following steps are carried out in turn: a layer of molybdenum trioxide is evaporated on the ITO glass; a first hole transport layer is evaporated with high glass transition temperature; a layer of TCTA is evaporated as the second hole transport layer; a luminescent layer containing (dfppy)2Ir(ppp) and the host material 26DCzPPy is co-evaporated; a layer of TmPyPB is evaporated as the electron transport layer; a layer of LiF is evaporated; a layer of Al is evaporated.

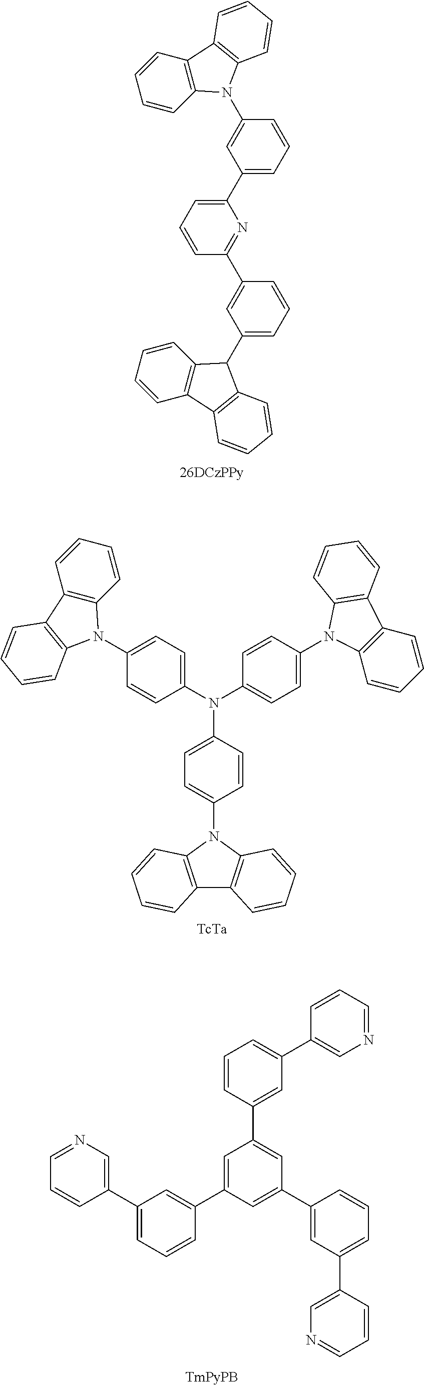

The fabricated device is tested at 50° C., in order to obtain data about it. The stability of the reference device (serial number 1) is defined as 1, and the stability is defined as the time when the luminescent efficiency is reduced to 50% of the original luminescent efficiency. The comparative data are as follows:

| Serial | Metal | First hole | Turn on | |
|---|---|---|---|---|
| number | complex | transport material | voltage | Stability |
| 1 | FIrpic | TAPC | 3.3 V | 1 |
| 2 | (dfppy)2Ir(ppp) | BPD | 3.4 V | 10 |
| 3 | (dfppy)2Ir(ppp) | TTA | 3.2 V | 15 |
| 4 | (dfppy)2Ir(ppp) | Without the first | 3.7 V | 1.5 |
| | | hole transport material | | |

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A phosphorescence device containing a metal complex of heterocyclic phosphoric acid, wherein the phosphorescence device contains a metal complex of heterocyclic phosphoric acid auxiliary ligands, and the glass transition temperature of the hole transport material of the phosphorescence device is not less than 85° C., and the auxiliary ligands of the metal complexes are as shown in the general formula (I): 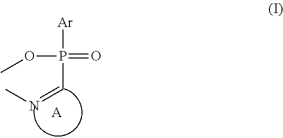
where, ring A is an aromatic group with at least a nitrogen atom, and Ar is an aromatic group.

2. The phosphorescence device as described in claim 1, wherein the hole transport material has one of the following structures: 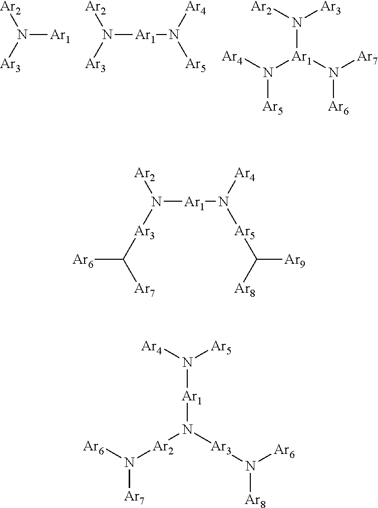
where, Ar₁, Ar₂, Ar₃, Ar₄, Ar₅, Ar₆, Ar₇, Ar₈ and Ar₉ are expressed independently: aromatic groups, nitrogen-containing aromatic groups, oxygen-containing aromatic groups, sulfur-containing aromatic groups, Aromatic groups containing boron, aromatic groups containing silicon or aromatic groups containing phosphorus.

3. The phosphorescence device as described in claim 2, wherein the aromatic group is replaced by a substituted group, the substituents are hydrogen atom, deuterium atom, halogen, alkyl, naphthyl, hetero-alkyl, aromatic alkyl, alkoxy, aryl, silyl, alkynyl, alkenyl, aryl, heteraryl, acyl, carbonyl, ester group, cyanide or its combination.

4. The phosphorescence device as described claim 2, wherein Ar₁, Ar₂, Ar₃, Ar₄, Ar₅, Ar₆, Ar₇, Ar₈, Ar₉ are selected from phenyl, biphenyl, triphenyl, tetraphenyl, toluene, tert-#china_person0# phenyl, Methoxy, naphthyl, anthracene, phenanthroline, pyrene, benzophenyl, carbazole, thiophene or fluorene independently, respectively.

5. The phosphorescence device as described in claim 1, wherein the glass transition temperature of the hole transport material is greater than 90° C.

6. The phosphorescence device as described in claim 5, wherein the glass transition temperature of the hole transport material is greater than 100° C.

7. The phosphorescence device as described in claim 6, wherein the glass transition temperature of the hole transport material is greater than 110° C.

8. The phosphorescence device as described in claim 7, wherein the hole transport material has a hole injection function and an electron barrier function.

9. The phosphorescent device as described in claim 1 comprising one of the following structures of the hole transport material:

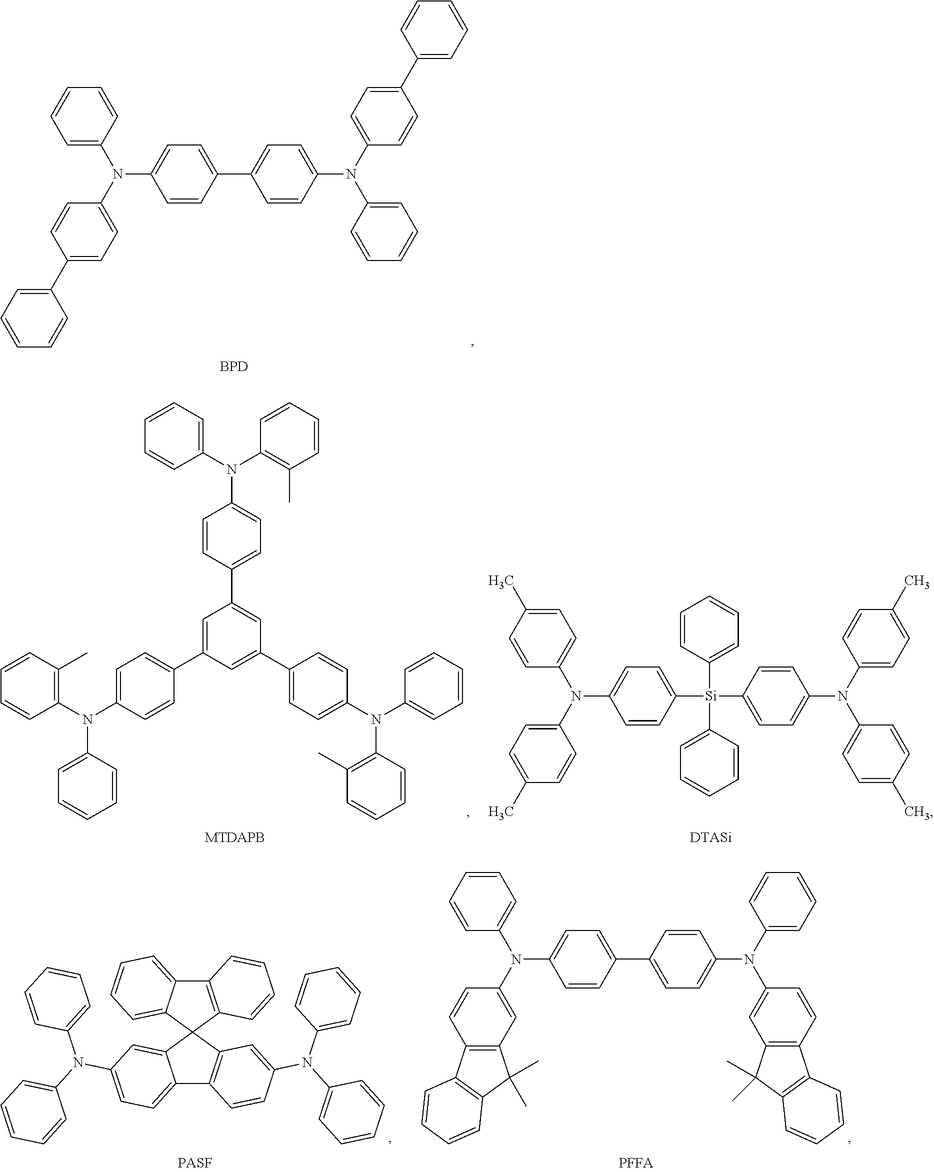

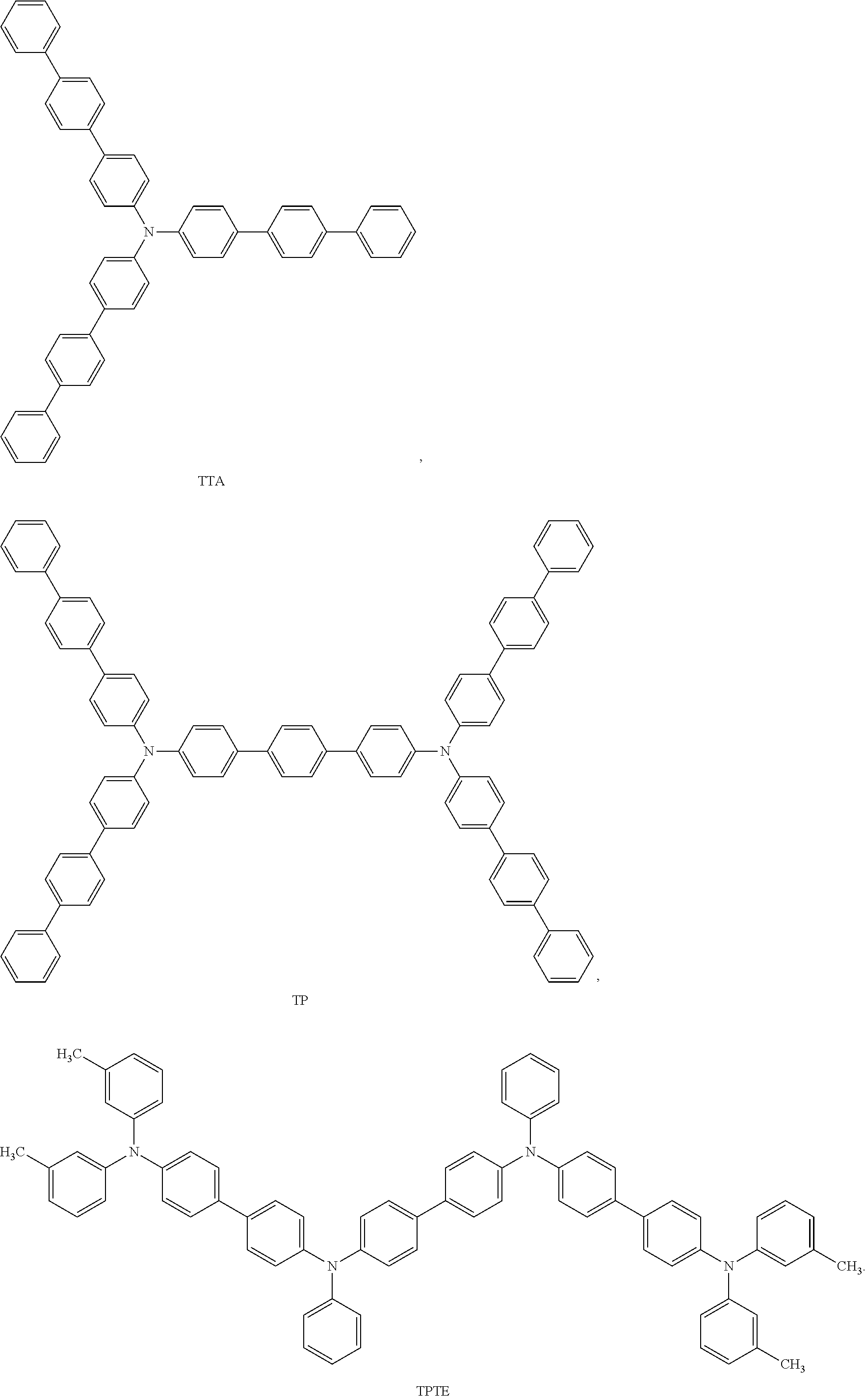

10. The phosphorescence device as described in claim 1, wherein the metal of the metal complex is Ir, Pt, Os or Ru.

11. The phosphorescence device as described in claim 1, wherein the metal complex also includes a principal ligand, and the principal ligand has the structure shown by the general (II): 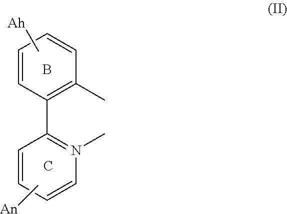
where, ring B is a six-member ring, ring C is a nitrogen-containing heterocyclic, Ah, An are substituent groups;
Ah and An are one or more independently, respectively, and each Ah is hydrogen, deuterium, halogen, alkyl, halogen substituted alkyl, aryl, hetero-aryl or cyanide independently, respectively; Each An is hydrogen, deuterium, halogen, alkyl, alkoxy, aryl, hetero-aryl, aramido or hetero-arylamine independently, respectively.

12. The phosphorescence device as described in claim 11, wherein the ring B is phenyl, pyridine ring, pyrimidine ring or pyrazine ring, and ring C is a pyridine ring, pyrimidine ring or pyrazine ring.

13. The phosphorescence device as described in claim 11, wherein the ring A and Ar are a single ring or a parallel ring independently, respectively.

14. The phosphorescence device as described in claim 13, wherein the ring A and Ar are a five-member ring or a six-member ring independently, respectively.

15. The phosphorescence device as described in claim 14, wherein the ring A and Ar are a six-member ring independently, respectively.

16. The phosphorescence device as described in claim 15, wherein the ring A is a pyridine ring, a pyrimidine ring, a pyrazine ring or a triazine ring; Ar is phenyl, pyridine, pyrimidine or pyrazine.

17. The phosphorescence device as described in claim 15, wherein the ring A and Ar are independently replaced by hydrogen atoms, deuterium atoms, fluorine atoms, alkyl, alkoxy, aryl or hetero-aryl groups respectively.
